(19) United States
(12) Patent Application Publication
(10) Pub. No.: US 2017/0006728 A1
(43) Pub. Date: Jan. 5, 2017

(54) ELECTRONIC DEVICE

(71) Applicants: HONG FU JIN PRECISION INDUSTRY (ShenZhen) CO., LTD, Shenzhen (CN); HON HAI PRECISION INDUSTRY CO., LTD., New Taipei (TW)

(72) Inventors: KANG WU, Shenzhen (CN); GUO-YI CHEN, Shenzhen (CN)

(21) Appl. No.: 14/806,192

(22) Filed: Jul. 22, 2015

(30) Foreign Application Priority Data
Jun. 30, 2015 (CN) 201510384601.1

(51) Int. Cl. H05K 7/14; H05K 7/20

(52) U.S. Cl. CPC H05K 7/1489; H05K 7/1492; H05K 7/1439; H05K 7/1452; H05K 7/20009

(57) ABSTRACT

An electronic device includes a motherboard, a backboard, and a connection board. The motherboard includes a plurality of hard disk drives (HDDs) connectors configured to electrically couple to a plurality of HDDs. The connection board includes a plurality of gold fingers and HDD connectors. The backboard includes a plurality of slots, a plurality of HDD connectors, and through holes. The HDD connectors of the motherboard are electrically coupled to the HDD connectors of the connection board. The gold fingers are electrically coupled to the slots correspondingly. The HDD connectors of the backboard are configured to transmit HDD signal from the HDDs to motherboard through the HDD connectors of the connection board.

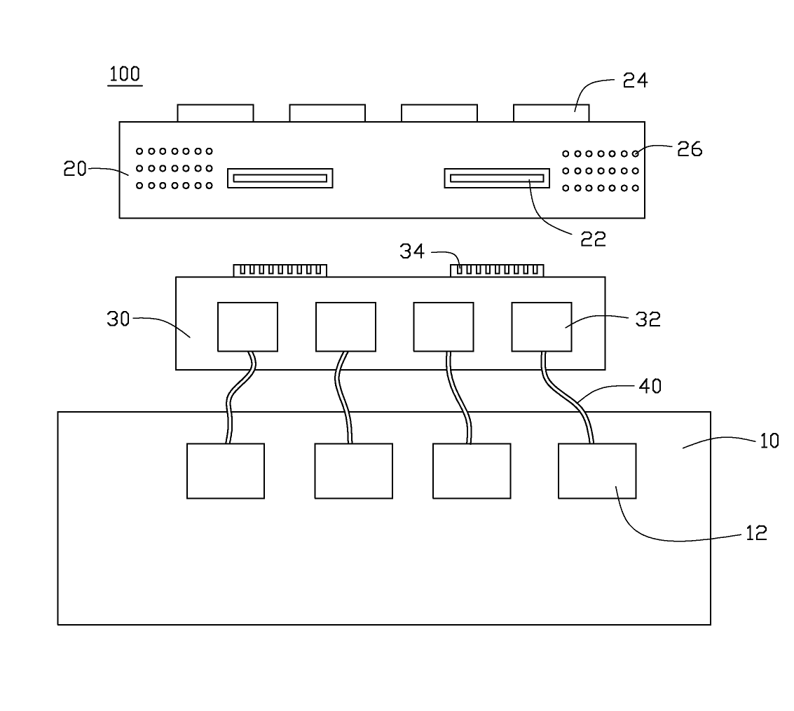

### FIELD

The subject matter herein generally relates to an electronic device.

### BACKGROUND

A backboard is usually applied in an electronic device, such as a server, and comprises a plurality of hard disk drive (HDD) connectors for coupling to a plurality of hard disk drives (HDDs) and a plurality of through holes for dissipating heat. However, if too much HDD connectors are set on the backboard, there will be not enough through holes to dissipating heat for the electronic device.

### BRIEF DESCRIPTION OF THE DRAWING

Implementations of the present technology will now be described, by way of example only, with reference to the attached figures.

The FIGURE is an isometric view of an example embodiment of an electronic device.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “electrically coupled” is defined as connected, whether directly or indirectly through intervening components, and is not necessarily limited to physical connections. The connection can be such that the objects are permanently electrically coupled or releasably electrically coupled. The term “comprising,” when utilized, means “including, but not necessarily limited to”; it specifically indicates open-ended inclusion or membership in the so-described combination, group, series and the like.

The disclosure will now be described in relation to an interface circuit.

The FIGURE illustrates an isometric view of an example embodiment of an electronic device 100. The electronic device 100 can comprise a motherboard 10, a backboard 20, and a connection board 30. The motherboard 10 is electrically coupled to the backboard 20 through the connection board 30. In at least one embodiment, the electronic device 100 is a server.

The backboard 20 can comprise two peripheral component interface express (PCIE) slots 22 and a plurality of hard drive device (HDD) connectors 24. In at least one embodiment, the PCIE slot 22 is set on a surface of the backboard 20. The plurality of HDD connectors 24 are set on an edge of the backboard 20. Each of the HDD connectors 24 are electrically coupled to one HDD correspondingly. A plurality of through holes 26 are set on the backboard 20, and configured to dissipating heat for the electronic device 100, and particularly for a chassis of the server.

The connection board 30 can comprise four mini serial attached small computer system interface (SAS) connectors 32 and two gold fingers 34. The SAS connectors 32 are set on a surface of the connection board 30. The gold fingers 34 are set on an edge of the connection board 30. The two gold fingers 34 are electrically coupled to the two PCIE slots 22 of the backboard 20 correspondingly, to make the mini SAS connectors 32 of the connection board 30 electrically coupling to the HDD connectors 24 of the backboard 20. Each of the mini SAS connectors 32 is electrically coupled to the four HDD connectors 24, for transmitting signal with four HDDs. The connection board 30 is perpendicular to the backboard 20.

The motherboard 10 can comprise a plurality of mini SAS connectors 12. Each of the mini SAS connectors 32 of the connection board 30 is electrically coupled to one mini SAS connector 12 of the motherboard 10 correspondingly through a plurality of cables 40, to make the motherboard 10 to transmit SAS signal with the connection board 30.

Numbers of the PCIE slots 22, through holes 26, and mini SAS connectors 32 can be changed according to an actual requirement. The number of the gold finger 34 is the same as that of PCIE slots 22.

In use, when the HDD connectors 24 of the backboard 20 are electrically coupled to HDDs, the HDD connectors 24 transmits the HDD signal to the mini SAS connectors 32 of the connection board 30 through the PCIE slots 22 of the backboard 20 and the gold fingers 34 of the connection board 30. The mini SAS connectors 32 transmits the HDD signal to the motherboard 10 through the cables 40.

While the disclosure has been described by way of example and in terms of the embodiment, it is to be understood that the disclosure is not limited thereto. On the contrary, it is intended to cover various modifications and similar arrangements as would be apparent to those skilled in the art. Therefore, the range of the appended claims should be accorded the broadest interpretation so as to encompass all such modifications and similar arrangements.

What is claimed is:

1. An electronic device comprising:
a motherboard comprising a plurality of hard disk drives (HDDs) connectors configured to electrically couple to a plurality of HDDs;
a backboard comprising a plurality of slots, a plurality of HDD connectors, and a plurality of through holes;
a connection board electrically coupled to the motherboard and the backboard, and comprising a plurality of gold fingers and a plurality of HDD connectors,
wherein the HDD connectors of the connection board are electrically coupled to the HDD connectors of the motherboard through a plurality of cables; the gold fingers are electrically coupled to the slots correspondingly; the HDD connectors of the backboard is configured to transmit HDD signal from the HDDs to the HDD connectors of the connection board through the slots and the gold fingers; the HDD connectors of the connection board transmits the HDD signal to the motherboard through the cables.

2. The electronic device of claim 1, wherein backboard is perpendicular to the connection board.

3. The electronic device of claim 2, wherein number of the HDD connectors of the motherboard is the same as that of the connection board.

4. The electronic device of claim 3, wherein the HDD connectors of the motherboard and the connection board are mini serial attached small computer system interface (SAS) connectors, each SAS connector is electrically coupled to four HDD connectors of the backboard.

5. The electronic device of claim 1, wherein the slots on the backboard are peripheral component interface express (PCIE) slots.

6. The electronic device of claim 1, wherein the HDD connectors of the backboard are set on an edge of the backboard.

7. The electronic device of claim 1, wherein the gold fingers of the connection board are set on an edge of the connection board.

8. The electronic device of claim 1, wherein number of the gold fingers and the slots is two.
